(19) United States
(12) Patent Application Publication
(10) Pub. No.: US 2018/0366674 A1
(43) Pub. Date: Dec. 20, 2018

(54) SEMICONDUCTOR NANOPARTICLE, DISPERSION LIQUID, AND FILM

(71) Applicant: FUJIFILM Corporation, Tokyo (JP)

(72) Inventor: Tsutomu SASAKI, Ashigara-kami-gun (JP)

(73) Assignee: FUJIFILM Corporation, Tokyo (JP)

(21) Appl. No.: 16/115,052

(22) Filed: Aug. 28, 2018

Related U.S. Application Data
(63) Continuation of application No. PCT/JP2017/006567, filed on Feb. 22, 2017.

(30) Foreign Application Priority Data
Feb. 29, 2016 (JP) 2016-037585

(51) Int. Cl. H01L 51/50; H01L 51/00; H01L 31/055

(52) U.S. Cl. CPC H01L 51/502; B82Y 20/00; H01L 31/055; H01L 51/0092

(57) ABSTRACT

It is an object of the present invention to provide a semiconductor nanoparticle having an excellent durability, and a dispersion liquid and a film, each of which uses the semiconductor nanoparticle. The semiconductor nanoparticle according to the present invention includes a core containing a Group III element and a Group V element, in which the nanoparticle contains carbon, oxygen, and sulfur, as detected by X-ray photoelectron spectroscopy, has peak A located at 2800 cm⁻¹ to 3000 cm⁻¹, peak B located at 1000 cm⁻¹ to 1200 cm⁻¹, and peak C located at 2450 cm⁻¹ to 2650 cm⁻¹, as detected by Fourier transform infrared spectroscopy, and contains a ligand having two or more mercapto groups.

### CROSS-REFERENCE TO RELATED APPLICATIONS

This application is a Continuation of PCT International Application No. PCT/JP2017/006567 filed on Feb. 22, 2017, which claims priority under 35 U.S.C. § 119(a) to Japanese Patent Application No. 2016-037585 filed on Feb. 29, 2016. The above application is hereby expressly incorporated by reference, in its entirety, into the present application.

### BACKGROUND OF THE INVENTION

### 1. Field of the Invention

The present invention relates to a semiconductor nanoparticle, a dispersion liquid, and a film.

### 2. Description of the Related Art

Single nano-sized colloidal semiconductor nanoparticles (hereinafter, also referred to as “quantum dots”), obtained by a chemical synthesis method in a solution containing a metal element, have been put into practical use as fluorescent materials in wavelength conversion films for some display applications. In addition, quantum dots are expected to be applied to biological labels, light emitting diodes, solar cells, thin film transistors, and the like.

After suggestion of a hot soap method (also referred to as a hot injection method), which is a method of chemical synthesis of quantum dots, the research of quantum dots has been actively carried out around the world.

For example, JP2002-121549A discloses a “semiconductor ultrafine particle obtained by bonding a polyalkylene glycol residue to a surface of a semiconductor crystal” ([claim 1]), and discloses an aspect in which the polyalkylene glycol residue is bonded to the surface of the semiconductor crystal through a ω-mercapto fatty acid residue ([claim 2]).

Further, JP4181435B discloses a “water-soluble polyethylene glycol-modified semiconductor fine panicle obtained by bonding a polyethylene glycol having a thiol group at least at one terminal and having a number-average molecular weight of 300 to 20000 to a Group II-VI semiconductor microcrystal having a core-shell structure having a ZnO, ZnS, ZnSe, or ZnTe shell through cadmium” ([claim 1]).

On the other hand, it has been reported in Edmond Gravel et al., “Compact tridentate ligands for enhanced aqueous stability of quantum dots and in vivo imaging” Chem. Sci., 2013, 4, 411 that a ligand having a polyethylene glycol (hereinafter, also abbreviated as “PEG”) chain and represented by TMM-PEG 2000 (1) shown below is introduced into a cadmium (Cd)-based quantum dot.

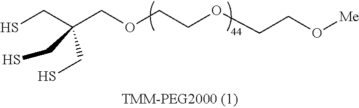

In addition, it has been reported in Betty R. Liu et al., “Synthesis, characterization and applications of carboxylated and polyethylene-glycolated bifunctionalized InP/ZnS quantum dots in cellular internalization mediated by cell penetrating peptides” Colloids and Surfaces B: Biointerfaces 111 (2013) 162 that 1,2-distearoyl-sn-glycero-3-phosphoethanolamine-N-(methoxy(polyethylene glycol)-2000) is coordinated to InP/ZnS using an intermolecular force with palmitic acid.

### SUMMARY OF THE INVENTION

From the viewpoint of avoiding regulations such as Restriction on Hazardous Substances (Rohs), the present inventors have attempted to apply the ligands used for Cd-based quantum dots described in each of the foregoing documents (in particular, JP4181435B and Edmond Gravel et al., “Compact tridentate ligands for enhanced aqueous stability of quantum dots and in vivo imaging” Chem. Sci., 2013, 4, 411) to quantum dots of Group III elements such a indium (In)-based quantum dots and then found that, depending on the structure of the ligand, the luminous efficiency of the obtained semiconductor nanoparticles may be inferior in some cases, or the luminescence stability thereof against ultraviolet rays or the like thereinafter also referred to as “durability”) may be inferior in some cases.

Accordingly, an object of the present invention is to provide a semiconductor nanoparticle having an excellent durability, and a dispersion liquid and a film, each of which uses the semiconductor nanoparticle.

As a result of extensive studies to achieve the foregoing object, the present inventors have found that the durability of a semiconductor nanoparticle is improved in the case where a semiconductor nanoparticle obtained by introducing a specific ligand is a semiconductor nanoparticle in which a predetermined element is detected by X-ray photoelectron spectroscopy and a predetermined peak is detected by Fourier transform infrared spectroscopy. The present invention has been completed based on these findings.

That is, it has been found that the foregoing object can be achieved by the following constitution.
[1] A semiconductor nanoparticle comprising a core containing a Group III element and a Group V element, in which the nanoparticle contains carbon, oxygen, and sulfur, as detected by X-ray photoelectron spectroscopy, has peak A located at 2800 cm⁻¹ to 3000 cm⁻¹, peak B located at 1000 cm⁻¹ to 1200 cm⁻¹, and peak C located at 2450 cm⁻¹ to 2650 cm⁻¹, as detected by Fourier transform infrared spectroscopy, and contains a ligand having two or more mercapto groups.
[2] The semiconductor nanoparticle according to [1], in which, a peak intensity ratio between peak A and peak B satisfies Equation (1).

0<peak B/peak A<2.5 (1)
[3] The semiconductor nanoparticle according to [1] or [2], in which the peak intensity ratio between peak A and peak C satisfies Equation (2).

0<peak C/peak A<0.15 (2)

[4] The semiconductor nanoparticle according to any one of [1] to [3], in which the ligand has structure 1 represented by any one of Formulae (Ia), (Ib), and (Ic), structure II represented by Formula (IIa), and structure III represented by a hydrocarbon group other than structure I and structure II.

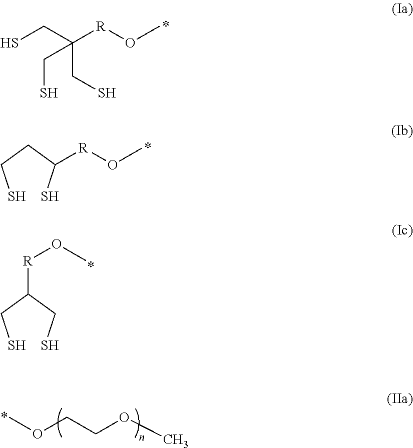

In which * in Formulae (Ia) to (Ic), and (IIa) represents a bonding position, R in Formulae (Ia) to (Ic) represents an aliphatic hydrocarbon group having 1 to 8 carbon atoms, and n in Formula (IIa) represents an integer of 1 to 8.
[5] The semiconductor nanoparticle according to [4], in which the ligand has structure III between structure I and structure II,
n in Formula (IIa) is an integer of 1 to 5, and
the hydrocarbon group constituting structure III is a linear aliphatic hydrocarbon group having 8 to 25 carbon atoms.
[6] The semiconductor nanoparticle according to any one of [1] to [5], in which the ligand has an average molecular weight of 300 to 1000.

[7] The semiconductor nanoparticle according to any one of [1] to [6], in which the ligand has structure IV represented by any one of formulae (IVa), (IVb), and (IVc).

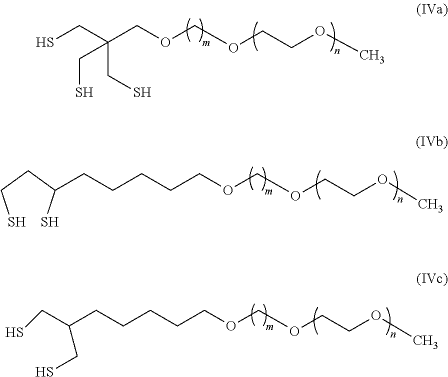

In which, in Formulae (IVa) to (IVe), m represents an integer of 8 to 13 and n represents an integer of 2 to 5.
[8] The semiconductor nanoparticle according to any one of [1] to [7], which has a core containing a Group III element and a Group V element and a shell containing a Group II element and a Group VI element and covering at least a part of the surface of the core.

The semiconductor nanoparticle according to any one of [1] to [7], which has a core containing a Group III dement and a Group V element, a first shell covering at least a part of the surface of the core, and a second shell covering at least a part of the first shell.

The semiconductor nanoparticle according to [8] or [9], in which the Group III element contained in the core is In and the Group V element contained in the core is any one of P, N, and As.

The semiconductor nanoparticle according to [10], in which the Group III element contained in the core is In and the Group V element contained in the core is P.

The semiconductor nanoparticle according to any one of [8] to [11], in which the core further contains a Group II element.

The semiconductor nanoparticle according to [12], in which the Group II element contained so the core is Zn.

The semiconductor nanoparticle according to any one of [9] to [13], in which the first shell contains a Group II element or a Group III element, provided that, in the case where the line shell contains a Group III element, the Group III element contained in the first shell is a Group III element different from the Group III element contained in the core.

The semiconductor nanoparticle according to any one of [9] to [14], in which the first shell is a Group II-VI semiconductor containing a Group II element and a Group VI element, or a Group III-V semiconductor containing a Group III element and a Group V element, provided that, in the case where the first shell is a Group III-V semiconductor, the Group III element contained in the Group III-V semiconductor is a Group III element different from the Group III element contained in the core.

The semiconductor nanoparticle according to [15], in which, in the case where the first shell is a Group II-VI semiconductor, the Group II element is Zn and the Group VI element is Se or S, and
in the case where the first shell is a Group III-V semiconductor, the Group III element is Ga and the Group V element is P.

The semiconductor nanoparticle according to [15], in which the first shell is a Group III-V semiconductor, the Group III element is Ga, and the Group V element is P.

The semiconductor nanoparticle according to any one of [9] to [17], in which the second shell is a Group II-VI semiconductor containing a Group II element and a Group VI element, or a Group III-V semiconductor containing a Group III element and a Group V element.

The semiconductor nanoparticle according to [18], in which the second shell is a Group II-VI semiconductor, the Group II element is Zn, and the Group VI element is S.

The semiconductor nanoparticle according to any one of [9] to [19], in which the core, the first shell, and the second shell are all crystal systems having a zinc blende structure.

The semiconductor nanoparticle according to any one of [9] to [20], in which, among the core, the first shell, and the second shell, the core has the smallest band gap, and the core and the first shell exhibit a type 1 band structure.

A dispersion liquid containing the semiconductor nanoparticle according to any one of [1] to [21].

A film containing the semiconductor nanoparticle according to any one of [1] to [21].

According to the present invention, provided are a semiconductor nanoparticle having an excellent durability, and a dispersion liquid and a film, each of which uses the semiconductor nanoparticle.

### DESCRIPTION OF THE PREFERRED EMBODIMENTS

Hereinafter, the present invention will be described in detail.

Descriptions of the constituent features described below are sometimes made based on representative embodiments of the present invention, but the present invention is not limited to such embodiments.

In the present specification, a numerical range expressed using “to” means a range including numerical values described before and after “to” as a lower limit value and an upper limit value, respectively.

[Semiconductor nanoparticle]

The semiconductor nanoparticle of the present invention is a semiconductor nanoparticle having a core containing a Group III element and a Group V element, in which the nanoparticle contains carbon, oxygen, and sulfur, as detected by X-ray photoelectron spectroscopy (hereinafter, also referred to as “XPS”), and has peak A located at 2800 cm⁻¹ to 3000 cm⁻¹, peak B located at 1000 cm⁻¹ to 1200 cm⁻¹, and peak C located at 2450 cm⁻¹ to 2650 cm⁻¹, as detected by Fourier transform infrared spectroscopy (hereinafter, also referred to as “FT-IR”).

In addition, the semiconductor nanoparticle of the present invention has a ligand containing two or more mercapto groups.

In the present invention, the detection of carbon, oxygen, and sulfur by XPS is determined based on whether or not carbon, oxygen, and sulfur are detected in the case of being measured under the following measurement conditions.

In addition, the peak intensity of an element detected by XPS is an area intensity obtained by subtracting the background from the peak observed under the following measurement conditions and integrating the area of the peak with respect to the energy.

In addition, the XPS measurement is carried out using a sample obtained by applying a dispersion liquid (solvent: toluene) containing semiconductor nanoparticles onto a non-doped Si substrate and then drying it.
<Measurement condition>
   Measuring device: XPS, Quantera SXM manufactured by Ulvac-PHI, Inc.
   X-ray source: Al-Kα rays (analysis diameter 100 μm, 25 W, 15 kV)
   Photoelectron take-off angle: 45°
   Measurement range: 300 μm×300 μm
   Correction: Charge correction by combined use of electron gun and low speed ion gun
   Measuring elements (measuring orbits): C(1s), N(1s), O(1s), Si(2p), P(2p), S(2p), Cl(2p), Zn(2p3/2), Ga(2p3/2), In(3d5/2)

In the present invention, the detection of peak A, peak B, and peak C by FT-IR is determined based on whether or not peak A, peak B, and peak C are detected in the case of being measured under the following measurement conditions.

Further, the peak intensity ratio between peak A and peak B or peak C refers to a ratio of maximum peak intensity of peak (I_{COO}) to maximum peak intensity of peak (I_{CH3}), obtained by subtracting the background from each peak observed under the following measurement conditions.

In the FT-IR measurement, a dispersion liquid containing semiconductor nanoparticles is added dropwise directly on a detection unit using diamond attenuated total reflection (ATR) and sufficiently dried, and then the measurement is carried out under the following conditions. Solvents suitable for dispersibility of semiconductor nanoparticles are selected from toluene, acetone, ethanol, and the like.
<Measurement conditions>
   Measuring device: Nicolet 4700 (manufactured by Thermofisher Scientific Inc.)
   Detector: DTGS KBr
   Light source: IR
   Measurement accessories: Diamond ATR (direct dropwise addition of solution)
   Beam splitter; KBr
   Measuring wave number: 400 to 4000 cm⁻¹
   Measurement interval: 1.928 cm⁻¹
   Scan count: 32
   Resolution: 4

In the present invention, as described above, in the case where the semiconductor nanoparticle contains carbon, oxygen, and sulfur as detected by XPS, exhibits peak A, peak B, and peak C as detected by FT-IR, and has a ligand containing two or more mercapto groups, the durability of the semiconductor nanoparticle is improved.

Although the reason that the durability is improved like this is not clear, it is presumed to be approximate as follows.

Here, it is considered that the peak A located at 2800 cm⁻¹ to 3000 cm⁻¹ is mainly a peak derived from a hydrocarbon group (C-H stretching) (hereinafter, the peak A is also referred to as “I_{CH}”). For example, it is considered that the peak A is a peak showing that a hydrocarbon group constituting Structure III to be described later is present.

In addition, it is considered that the peak B located at 1000 cm⁻¹ to 1200 cm⁻¹ is mainly a peak derived from C-O-C stretching that constitutes the PEG chain (hereinafter, the peak B is also referred to as “I_{PEG}”). For example, it is considered that the peak B is a peak showing that a hydrocarbon group constituting the PEG chain of Structure II to be described later is present.

In addition, it is considered that the peak C located at 2450 cm⁻¹ to 2650 cm⁻¹ is mainly a peak derived from a mercapto group (S-H stretching) (hereinafter, the peak C is also referred to as “I_{SH}”). For example, it is considered that the peak C is a peak showing that a mercapto group in Structure I to be described is present.

Therefore, it is considered that the reason that the durability is improved as above is because, in the present invention, the coordination force of the ligand containing two or more mercapto groups with respect to the surface of the semiconductor nanoparticle is improved, and as a result, desorption of the ligand hardly occurs, so that the occurrence of surface defects could be suppressed.

Since the semiconductor nanoparticle of the present invention has a high luminous efficiency (particularly, initial luminous efficiency), the peak intensity ratio (I_{PEG}/I_{CH}) between peak A (I_{CH}) and peak B (I_{PEG}) detected by FT-IR preferably satisfies Equation (1), more preferably satisfies Equation (1-1), and still more preferably satisfies Equation (1-2).

0<peak B/peak A<2.5 (1)

0.1 <peak B/peak A<2.0 (1-1)

0.5 <peak B/peak A<1.5 (1-2)

From the viewpoint that the semiconductor nanoparticle of the present invention has a better durability, the peak intensity ratio (I_{SH}/I_{CH}) between peak A (I_{CH}) and peak C (I_{SH}) detected by FT-IR preferably satisfies the following Equation (2), more preferably satisfies Equation (2-1), and still more preferably satisfies Equation (2-2).

0<peak C/peak A<0.15 (2)

0.01<peak C/peak A<0.10 (2-1)

0.05<peak C/peak A<0.10 (2-2)

[Ligand]

The semiconductor nanoparticle of the present invention has a ligand containing two or more mercapto groups.

The ligand is not particularly limited as long as it has two or more mercapto groups, but from the viewpoint of preventing the aggregation of the quantum dots, the ligand preferably has a hydrocarbon group (for example, a linear aliphatic hydrocarbon group).

Further, from the viewpoint of dispersibility in various solvents, the ligand preferably has a PEG chain.

Further, from the viewpoint of durability, the ligand preferably has three mercapto groups.

In the present invention, the ligand preferably has Structure I represented by anyone of Formulae (Ia), (Ib), and (Ic), Structure II represented by Formula (IIa), and Structure III represented by a hydrocarbon group other than Structure I and Structure II. In the following formulae, * represents a bonding position.

Regarding Structure III, the expression “hydrocarbon group other than Structure I and Structure II” as used herein is a provision intending that the hydrocarbon group constituting Structure III is a hydrocarbon group different from the hydrocarbon group contained in Structure I and Structure II (for example, R or the like in Formula (Ia)).

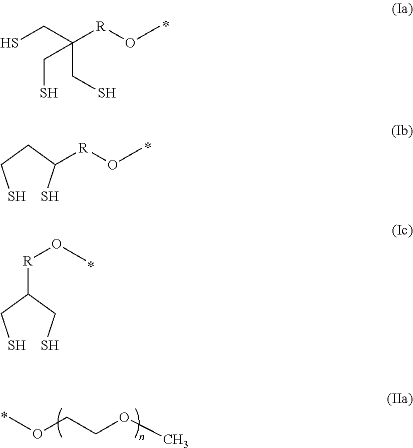

In Formulae (Ia) to (Ic), R represents an aliphatic hydrocarbon group having 1 to 8 carbon atoms, and is preferably an aliphatic hydrocarbon group having 1 to 6 carbon atoms.

Examples of the aliphatic hydrocarbon group having 1 to 8 carbon atoms include an alkylene group such as a methylene group, an ethylene group, a propylene group, an isopropylene group, a butylene group, a pentylene group, or a hexylene group; an alkenylene group such as a vinylene group (—CH═CH—); an alkyne such as internal alkyne (—CH≡CH—); and a linking group formed by combining these groups.

In Formula (IIa), n represents an integer of 1 to 8, preferably an integer of 1 to 5, and more preferably an integer of 2 to 5.

In the present invention, it is preferred that the ligand has Structure III between Structure I and Structure II described above, and n in Formula (IIa) representing Structure II is an integer of 1 to 5, and the hydrocarbon group constituting Structure III is a linear aliphatic hydrocarbon group having 8 to 25 carbon atoms.

Here, examples of the linear aliphatic hydrocarbon group having 8 to 25 carbon atoms include alkylene groups such as an octylene group, a nonylene group, a decylene group, a dodecylene group, and a hexadecylene group. In the present invention, the linear aliphatic hydrocarbon group may be a linking group formed by combining an alkylene group having 6 or less carbon atoms and a vinylene group (—CH═CH—), a linking group formed by combining an alkylene group having 5 or less carbon atoms, a vinylene group (—CH═CH—), and an alkylene group having 5 or less carbon atoms, or the like, as long as it is a linear aliphatic hydrocarbon group having a total of 8 to 25 carbon atoms.

In the present invention, the ligand preferably has an average molecular weight of 300 to 1000 and more preferably 400 to 900.

Here, the average molecular weight is measured using matrix assisted laser desorption/ionization time of flight mass spectrometry (MALDI TOF MS).

In the present invention, from the viewpoints of initial characteristics, durability, aggregation prevention, and dispersibility, the ligand preferably has Structure IV represented by any one of Formulae (IVa), (IVb), and (IVc), and more preferably a structure represented by Formula (IVa).

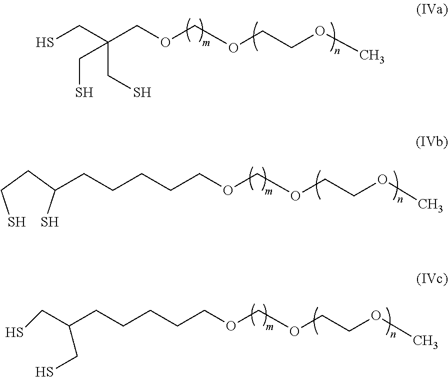

In Formulae (IVa) to (IVc), m represents an integer of 8 to 13, and n represents an integer of 2 to 5.

The particle shape of the semiconductor nanoparticle of the present invention is not particularly limited, as long as the semiconductor nanoparticle has a core containing a Group III element and & Group V element, and contains carbon, oxygen, and sulfur as detected by XPS, and has peak A (I_{CH}), peak B (I_{PEG}), and peak C (I_{SH}) as detected by FT-IR. For example, the particle shape of the semiconductor nanoparticle of the present invention is preferably a core shell shape such as a shape having a core containing a Group III element and a Group V element and a shell containing a Group II element and a Group VI element covering at least a part of the surface of the core (single shell shape); or a shape having a core containing a Group III element and a Group V element, a first shell covering at least a part of the surface of the core, and a second shell covering at least a part of the first shell (multi-shell shape); among which a multi-shell shape is preferable.

In the case where the semiconductor nanoparticle of the present invention is a core shell particle, the core of the core shell particle is a so-called Group III-V semiconductor containing a Group III element and a Group V element.

<Group III element>

Specific examples of the Group III element include indium (In), aluminum (Al), and gallium (Ga), among which In is preferable.

<Group V elements>

Specific examples of the Group V element include phosphorus (P), nitrogen (N), and arsenic (As), among which P is preferable.

In the present invention, a Group III-V semiconductor obtained by appropriately combining the Group III element and the Group V element exemplified above can be used as the core, but InP, InN, or InAs is preferable from the viewpoint that the luminous efficiency is further increased, the luminous half-width is narrowed, and a clear exciton peak is obtained. Among them, InP is more preferable from the viewpoint of further increasing the luminous efficiency.

In the present invention, it is preferred that the core further contains a Group II element in addition to the Group III element and the Group V element described above. In particular, in the case where the core is InP, the lattice constant is decreased by doping Zn as the Group II element and therefore the lattice matching performance with a shell (for example, GaP, ZnS, or the like which will be described below) having a smaller lattice constant than that of InP becomes higher.

[Shell]

In the case where the semiconductor nanoparticle of the present invention is a single shell-shaped core shell particle, the shell is a material covering at least a part of the surface of the core and is preferably a so-called Group II-VI semiconductor containing a Group II element and a Group VI element.

Here, in the present invention, whether or not at least a part of the surface of the core is covered with the shell can also be confirmed based on the composition distribution analysis by, for example, transmission electron microscope (TEM)-energy dispersive X-ray spectroscopy (EDX).

<Group II element>

Specific examples of the Group II element include zinc (Zn), cadmium (Cd), and magnesium (Mg), among which Zn is preferable.

<Group VI element>

Specific examples of the Group VI element include sulfur (S), oxygen (O), selenium (Se), and tellurium (Te), among which S or Se is preferable, and S is more preferable.

In the present invention, a Group II-VI semiconductor obtained by appropriately combining the Group II element and the Group VI element described above can be used as the shell, but it is preferred that the shell is a crystal system which is the same as or similar to the core described above.

Specifically, ZnS or ZnSe is preferable and ZnS is more preferable.

[First shell]

In the case where the semiconductor nanoparticle of the present invention is a multi-shell shaped core shell particle, the first shell is a material covering at least a part of the surface of the core.

Here, in the present invention, whether or not at least a part of the surface of the core is covered with the first shell can also be confirmed based on the composition distribution analysis by, for example, transmission electron microscope-energy dispersive X-ray spectroscopy (TEM-EDX).

In the present invention, from the viewpoint of easily suppressing defects of the interface between the core and the first shell, it is preferred that the first shell contains a Group II element or a Group III element.

Here, in the case where the first shell contains a Group III element, the Group III element contained in the first shell is a Group III element different from the Group III element contained in the core described above.

Further, in addition to a Group II-VI semiconductor and a Group III-V semiconductor described below, a Group III-VI semiconductor (for example, Ga₂O₃ or Ga₂S₃) containing a Group III element and a Group VI element may be exemplified as the first shell containing a Group II element or a Group III element.

In the present invention, from the viewpoint of obtaining an excellent crystal phase with less defects, it is preferred that the first shell is a Group II-VI semiconductor containing a Group II element and a Group VI element or a Group III-V semiconductor containing a Group III element and a Group V element and it is more preferred that the first shell is a Group III-V semiconductor in which a difference in lattice constant between the core described above and the first shell is small.

Here, in the case where the first shell is a Group III-V semiconductor, the Group III element contained in the Group III-V semiconductor is a Group III element different from the Group III element contained in the core described above.

<Group II-VI semiconductor>

Specific examples of the Group II element contained in the Group II-VI semiconductor include zinc (Zn), cadmium (Cd), and magnesium (Mg), among which Zn is preferable.

Specific examples of the Group VI element contained in the Group II-VI semiconductor include sulfur (S), oxygen (O), selenium (Se), and tellurium (Te), among which S or Se is preferable, and S is more preferable.

A Group II-VI semiconductor obtained by appropriately combining the Group II element and the Group VI element described above can be used as the first shell, but it is preferred that the first shell is a crystal system (for example, a zinc blende structure) which is the same as or similar to the core described above. Specifically, ZnSe, ZnS, or a mixed crystal thereof is preferable and ZnSe is more preferable.

<Group III-V semiconductor>

Specific examples of the Group III element contained in the Group III-V semiconductor include indium (In), aluminum (Al), and gallium (Ga), among which Ga is preferable. As described above, the Group III element contained in the Group III-V semiconductor is a Group III element different from the Group III element contained in the core described above. For example, in the case where the Group III element contained in the core is In, the Group III element contained in the Group III-V semiconductor is Al, Ga, or the like.

Specific examples of the Group V element contained in the Group III-V semiconductor include P (phosphorus), N (nitrogen), and As (arsenic), among which P is preferable.

A Group III-V semiconductor obtained by appropriately combining the Group III element, and the Group V element described above can be used as the first shell, but it is preferred that the first shell is a crystal system (for example, a zinc blende structure) which is the same as or similar to the core described above. Specifically, GaP is preferable.

In the present invention, from the viewpoint of reducing defects of the surface of the core shell particle to be obtained, it is preferred that a difference in lattice constant between the core and the first shell is small. Specifically, it is preferred that the difference in lattice constant between the core and the first shell is 10% or less.

Specifically, in the ease where the core is InP, as described above, it is preferred that the first shell is ZnSe (difference in lattice constant: 3.4%) or GaP (difference in lattice constant: 7.1%). Particularly, it is more preferred that the first shell is the same Group III-V semiconductor as the core and the Group III-V semiconductor is GaP from the viewpoint that a mixed crystal state can be easily made on the interface between the core and the first shell.

In the present invention, in the case where the first shell is a Group III-V semiconductor, the first shell may contain or dope another element (for example, the Group II element or the Group VI element described above) within the range that does not affect the magnitude correlation (core<first shell) of the band gap between the core and the first shell. Similarly, in the case where the first shell is a Group II-VI semiconductor, the first shell may contain or dope another element (for example, the Group III element or the Group V element described above within the range that does not affect the magnitude correlation (core<first shell) of the band gap between the core and the first shell.

[Second shell]

In the case where the semiconductor nanoparticle of the present invention is a multi-shell shaped core shell particle, the second shell is a material covering at least a part of the surface of the first shell described above.

Here, in the present invention, whether or not at least a part of the surface of the first shell is covered with the second shell can also be confirmed based on the composition distribution analysis by, for example, transmission electron microscope-energy dispersive X-ray spectroscopy (TEM-EDX).

In the present invention, from the viewpoints of suppressing defects of the interface between the first shell and the second shell and obtaining an excellent crystal phase with less defects, it is preferred that the second shell is a Group II-VI semiconductor containing a Group II element and a Group VI element or a Group III-V semiconductor containing a Group III element and a Group V element. Further, from the viewpoints of high reactivity of the material itself and easily obtaining a shell with excellent crystallinity, it is more preferred that the second shell is a Group II-VI semiconductor.

Examples of the Group II element and the Group VI element, and the Group III element and the Group V element include those described in the section of the first shell.

A Group II-VI semiconductor obtained by appropriately combining the Group II element and the Group VI element described above can be used as the second shell, but it is preferred that the second shell is a crystal system (for example, a zinc blende structure) which is the same as or similar to the core described above. Specifically, ZnSe, ZnS, or a mixed crystal thereof is preferable and ZnS is more preferable.

A Group III-V semiconductor obtained by appropriately combining the Group III element and the Group V element described above can be used as the second shell, but it is preferred that the second shell is a crystal system (for example, a zinc blende structure) which is the same as or similar to the core described above. Specifically, Gap is preferable.

In the present invention, from the viewpoint of reducing defects of the surface of the core shell particle to be obtained, it is preferred that a difference in lattice constant between the first shell and the second shell is small. Specifically, it is preferred that the difference in lattice constant between the first shell and the second shell is 10% or less.

Specifically, in the case where the first shell is GaP, as described above, it is preferred that the second shell is ZnSe (difference in lattice constant: 3.8%) or ZnS (difference in lattice constant: 0.8%) and it is more preferred that the second shell is ZnS.

In the present invention, in the case where the second shell is a Group II-VI semiconductor, the second shell may contain or dope another element (for example, the Group III element or the Group V element described above) within the range that does not affect the magnitude correlation (core<second shell) of the band gap between the core and the second shell. Similarly, in the case where the second shell is a Group III-V semiconductor, the second shell may contain or dope another element (for example, the Group II element or the Group VI element described above) within the range that does not affect the magnitude correlation (core<second shell) of the band gap between the core and the second shell.

In the present invention, from the viewpoint, that epitaxial growth becomes easy and defects of an interface between layers are easily suppressed, it is preferred that each of the core, the first shell, and the second shell described above is a crystal system having a zinc blende structure.

In the present invention, from the viewpoint that the probability of excitons staying in the core becomes higher and the luminous efficiency is further increased, it is preferred that the band gap of the core from among the core, the first shell, and the second shell described above is the smallest and the core and the first shell are core shell particles having a type 1 (type 1) band structure.

[Average particle diameter]

From the viewpoints of easily synthesizing particles having a uniform size and easily controlling the emission wavelength using quantum size effects, the average particle diameter of the semiconductor nanoparticles of the present invention is preferably 2 nm or more and more preferably 10 nm or less.

Here, the average particle diameter refers to a value obtained by directly observing at least 20 particles using a transmission electron microscope, calculating the diameters of circles having the same area as the projected area of the particles, and arithmetically averaging these values.

[Method for producing core shell particles]

A method for producing semiconductor nanoparticles of synthesizing the semiconductor nanoparticle of the present invention (hereinafter, also referred to as “production method of the present invention” in a formal sense) is a method for producing semiconductor nanoparticles, having a mixing step of mixing semiconductor nanoparticles QD having no ligand with a ligand having two or more mercapto groups (hereinafter, abbreviated as “ligand A”).

Further, the production method of the present invention may have a leaving step of leaving (standing) after the mixing step. The coordination of the ligand A to the semiconductor nanoparticle QD may proceed in the mixing step or may proceed in the leaving step.

Here, the ligand A is the same as that described above for the semiconductor nanoparticle of the present invention.

Further, the semiconductor nanoparticle QD is a semiconductor nanoparticle known in the related art to which the ligand A is not coordinated, and is a semiconductor nanoparticle in which one or more peaks of peak A (I_{CH}), peak B (I_{PEG}), and peak C (I_{SH}) are not detected by FT-IR.

In the production method of the present invention, from the viewpoint that the ligand exchange of the ligand A easily proceeds, it is preferable to mix the semiconductor nanoparticles QD and the ligand A at 20° C. to 100° C., and it is more preferable to mix them at 50° C. to 85° C.

From the same viewpoint, in the case of including a leaving step, it is preferable to leave at 20° C. to 100° C., and it is more preferable to leave at 50° C. to 85° C.

In the production method of the present invention, from the viewpoint of suppressing the generation of defects, it is preferable to mix the semiconductor nanoparticles QD and the ligand A under a light shield and/or under a nitrogen atmosphere, and it is more preferable to mix them under a light shield and under a nitrogen atmosphere.

From the same viewpoint, in the case of including a leaving step, it is preferable to leave under a light shield and/or under a nitrogen atmosphere, and it is more preferable to leave under a light shield and under a nitrogen atmosphere.

In the production method of the present invention, from the viewpoint that the ligand exchange of the ligand A easily proceeds, it is preferable to carry out a mixing step of mixing the semiconductor nanoparticles QD and the ligand A for 8 hours or more, and it is more preferable to carry out the mixing step for 12 to 48 hours.

From the same viewpoint, in the case of including a leaving step, it is preferably carried out the step for 8 hours or more and more preferably 12 to 48 hours.

[Dispersion liquid]

The dispersion liquid of the present invention is a dispersion liquid containing the semiconductor nanoparticles of the present invention described above.

Here, the solvent constituting the dispersion medium of the dispersion liquid is preferably a nonpolar solvent.

Specific examples of the nonpolar solvent include an aromatic hydrocarbon such as toluene; a halogenated alkyl such as chloroform; an aliphatic saturated hydrocarbon such as hexane, octane, n-decane, n-dodecane, n-hexadecane, or n-octadecane; an aliphatic unsaturated hydrocarbon such as 1-undecene, 1-dodecene, 1-hexadecene, or 1-octadecene; and trioctylphosphine.

The content (concentration) of the semiconductor nanoparticles of the present invention in the dispersion liquid of the present invention is preferably 0.1 to 100 mol/L and more preferably 0.1 to 1 mol/L, with respect to the total mass of the dispersion liquid of the present invention.

[Film]

The film of the present invention is a film containing the semiconductor nanoparticles of the present invention described above.

Since such a film of the present invention has a high luminous efficiency and a good durability, the film can be applied to, for example, a wavelength conversion film for a display, a photoelectron conversion (or wavelength conversion) film of a solar cell, a biological label, a thin film transistor, and the like. In particular, since the film of the present invention exhibits an excellent durability against ultraviolet rays or the like, it is suitably applied to a down-conversion or down-shifting type wavelength conversion film which absorbs light in a region of shorter wavelengths than those of the absorption edge of quantum dots and emits light of longer wavelengths.

Further, the film material as a base material constituting the film of the present invention is not particularly limited and may be a resin or a thin glass film.

Specific examples thereof include resin materials mainly formed of an ionomer, polyethylene, polyvinyl chloride, polyvinylidene chloride, polyvinyl alcohol, polypropylene, polyester, polycarbonate, polystyrene, polyacrylonitrile, an ethylene vinyl acetate copolymer, an ethylene-vinyl alcohol copolymer, an ethylene-methacrylic acid copolymer film, nylon, and the like.

### EXAMPLES

Hereinafter, the present invention will be described in more detail with reference to Examples. The materials, the use amounts, the ratios, the treatment contents, the treatment procedures, and the like shown in the following Examples can be appropriately changed without departing from the gist of the present invention. Therefore, the scope of the present invention should not be limitatively interpreted by the following Examples.

<Synthesis of In-based semiconductor nanoparticles QD>

32 mL of octadecene, 140 mg (0.48 mmol) of indium acetate, and 48 mg (0.24 mmol) of zinc chloride were added to a flask, and the solution in the flask was heated and stirred at 110° C. under vacuum to sufficiently dissolve the raw material while degassing for 90 minutes.

Next, the temperature of the flask was raised to 300° C. under a nitrogen flow, and in the case where the temperature of the solution was stabilized, 0.24 mmol of tristrimethylsilylphosphine dissolved in about 4 mL of octadecene was added to the flask. Thereafter, the flask was heated for 120 minutes in a state in which the temperature of the solution was set to 230° C. It was confirmed that the color of the solution was red and particles (core) were formed.

Next, 30 mg (0.18 mmol) of gallium chloride and 125 μL (0.4 mmol) of oleic acid which were dissolved in 8 mL of octadecene were added to the solution in a state in which the solution was heated to 200° C., and the solution was further heated for approximately 1 hour, thereby obtaining a dispersion liquid of a core shell particle precursor including InP (core) doped with Zn and Gap (first shell).

Next, the dispersion liquid was cooled to room temperature, 220 mg (1.2 mmol) of zinc acetate was added thereto, the dispersion liquid was heated to 230° C., and the temperature thereof was maintained for approximately 4 hours. Next. 1.15 mL (4.85 mmol) of dodecanethiol was added to the dispersion liquid which was then heated to 240° C. After cooling the resulting dispersion liquid to room temperature, 293 mg (1.6 mmol) of zinc acetate was added again, and the solution was heated to 230° C. and kept for about 1 hour. Thereafter, 1.53 mL (6.5 mmol) of dodecanethiol was added again, and the dispersion liquid was heated to 240° C. After cooling the resulting dispersion liquid to room temperature, ethanol was added thereto, and centrifugation was carried out on the dispersion liquid so that particles were precipitated. The supernatant was discarded and the resultant was dispersed in a toluene solvent.

In this manner, a toluene dispersion liquid of core shell particles (InP/GaP/ZnS) including InP (core) doped with Zn, GaP (first shell) covering the surface of the core, and ZnS (second shell) covering the surface of the first shell was obtained.

Synthesis of Cd-based semiconductor nanoparticles QD>

Cd-based semiconductor nanoparticles were synthesized based on the reaction of the carboxylic acid precursor described in Edmond Gravel et al., “Compact tridentate ligands for enhanced aqueous stability of quantum dots and in vivo imaging” Chem. Sci, 2013, 4, 411 and the SILAR protocol.

Specifically, 60 mg of CdO, 280 mg of octadecylphosphonic acid (ODPA), and 3 g of trioctylphosphine oxide (TOPO) were added to a 50 mL flask, and the mixture was heated to 150° C., followed by degassing under vacuum for 1 hour. Nitrogen was then flowed thereinto and the reaction mixture was heated to 320° C. to form a clear colorless solution. Subsequently, 1.0 mL of trioctylphosphine (TOP) was added, and in the case where the temperature reached 380° C., an SE/TOP solution (60 mg of Se in 0.5 mL of TOP) was rapidly poured into the flask to synthesize CdSe core nanocrystals.

The shell growth reaction was carried out by filling a hexane solution containing 100 nanomoles of CdSe quantum dots in a mixture of 1-octadecene (ODE, 3 mL) and oleylamine (OAM, 3 mL).

The reaction solution was then degassed under vacuum at 120° C. for 1 hour and 20 minutes to completely remove hexane, water, and oxygen in the reaction solution.

Thereafter, the reaction solution was heated to 310° C. at a heating rate of 18° C./min under nitrogen flow and stirring. After the temperature reached 240° C., a desired amount of cadmium (II) oleic acid (Cd-oleic acid, dilated with 6 ml of ODE) and octanethiol (1.2 equivalents of Cd-oleic acid, dilated with 6 mL of ODE) was added dropwise and injected into the reaction solution at a rate of 3 mL/h using a syringe pump. After injection was completed, 1 mL of oleic acid was immediately injected and the solution was further annealed at 310° C. for 60 minutes. The CdSe/CdS core/shell quantum dots thus obtained were precipitated by adding acetone to obtain CdSe/CdS particles.

Thereafter, the mixture was further heated to 210° C., and a Zn:S stock solution was added dropwise thereto. The Zn:S stock solution was prepared by mixing 0.4 ml of a 1 M solution of Zn(C₂H₅)₂ in hexane, 0.1 mL of bis(trimethylsilyl)sulfide and 3 mL of TOP. After the growth of the ZnS shell was completed, the ZnS shell was overcoated with CdSe/CdS by cooling the reaction mixture to 90° C. and leaving it at this temperature for 1 hour.

### Examples 1 to 5

<Ligand exchange>

The concentration of the solution was adjusted such that the absorbance of the toluene dispersion liquid of the prepared core shell particles (InP/GaP/ZnS) was 0.2 at the excitation wavelength of 450 nm.

Next, while stirring the solution, ligands were added such that the molar ratio (core shell particle:ligand) of the core shell particles to each of the ligands A-1 to A-5 having the structure and molecular weight shown in Table 1 below becomes 1:600 as in Example 1, followed by sealing with nitrogen. In this state, the solution was kept at 65° C. and left for 24 hours under a light shield to proceed the ligand exchange, whereby semiconductor nanoparticles were prepared.

The structural formulae of the ligands A-1 to A-5 used in Examples 1 to 5 are shown below.

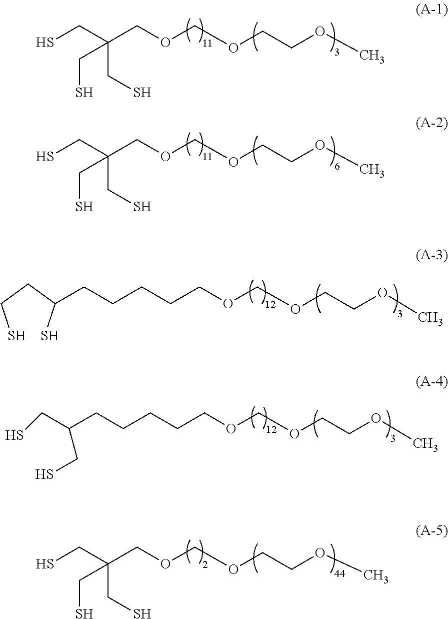

### Comparative Example 1

Semiconductor nanoparticles were prepared in the same manner as in Example 5, except that Cd-based semiconductor nanoparticles QD were used in place of the core shell particles (InP/GaP/ZnS).

### Comparative Example 2

According to the contents described in paragraph [0028] of JP4181435B, semiconductor nanoparticles having PEG introduced into CdSe-ZnS semiconductor microcrystals were prepared.

### Comparative Example 3

Semiconductor nanoparticles were prepared in the same manner as in Comparative Example 2, except that the prepared core shell particles (InP/GaP/ZnS) were used in place of the CdSe-ZnS semiconductor microcrystals.

### Comparative Example 4

Semiconductor nanoparticles having PEG introduced into CdSe/ZnS nanocrystals were prepared according to the contents described in paragraph [0070] of JP2002-121549A.

### Comparative Example 5

Semiconductor nanoparticles were prepared in the same manner as in Comparative Example 4, except that the prepared core shell particles (InP/GaP/ZnS) were used in place of the CdSe/ZnS nanocrystals.

[XPS]

With respect to dispersion liquids containing the prepared respective semiconductor nanoparticles, the presence or absence of the detection of carbon (C), oxygen (O), and sulfur (S) was measured by XPS according to the above-mentioned method. The results are shown in Table 1 below.

[FT-IR]

Each of dispersion liquids (the solvent is selected from toluene, acetone, ethanol, and the like) containing the respective semiconductor nanoparticles of Examples 1 to 5 and Comparative Example 1 adjusted to have an optical density (O.D.) at 450 nm of 0.05 to 0.1 was added dropwise into a diamond ATR type detection unit, and according to the above-mentioned method, the presence or absence of detection of peak A (I_{CH}), peak B (I_{PEG}), and peak C (I_{SH}) by FT-IR, and the peak intensity ratio B/A (I_{PEG}/I_{CH}) and the peak intensity ratio C/A (I_{SH}/I_{CH}) were measured. The results are shown in Table 1 below.

[Luminous efficiency]

<Initial>

The concentration of each of dispersion liquids containing the prepared respective semiconductor nanoparticles was adjusted such that the absorbance at an excitation wavelength of 450 nm was 0.2, and the luminescence intensity of the dispersion liquid was measured using a fluorescence spectrophotometer FluoroMax-3 (manufactured by Horiba Jobin Yvon SAS). The initial luminous efficiency was calculated by the comparison with a quantum dot sample whose luminous efficiency was known. The obtained luminous efficiency was calculated as a ratio of the number of emitted photons to the number of absorbed photons from excitation light. The results evaluated according to the following standards are shown in Table 1 below.
A: Initial luminous efficiency is 70% or more
B: Initial luminous efficiency is 65% or more and less than 70%
C: Initial luminous efficiency is 60% or more and less than 65%
D: Initial luminous efficiency is less than 60%

<Durability: after UV irradiation>

Each of dispersion liquids containing the prepared respective semiconductor nanoparticles was fixed, at a position of receiving 1 mW/cm² and irradiated with ultraviolet rays using a mercury lamp (wavelength: 365 nm). The irradiation amount of ultraviolet rays was 8 J/cm².

Thereafter, the luminous efficiency was measured in the same manner as in the initial luminous efficiency and evaluated according to the following standards for reduction from the initial luminous efficiency. The results are shown in Table 1 below.
a: Reduction from initial luminous efficiency is less than 5%
b: Reduction from initial luminous efficiency is 5% or more and less than 10%
c: Reduction from initial luminous efficiency is 10% or more and less than 15%
d: Reduction from initial luminous efficiency it 15% or more

<Durability: in the case of being diluted>

Toluene was added to dilute each of dispersion liquids containing the prepared respective semiconductor nanoparticles such that an optical density (O.D.) at 450 nm was 0.03, and then dispersion liquids were left in the atmosphere for 10 hours.

Thereafter, the luminous efficiency was measured in the same manner as in the initial luminous efficiency and evaluated according to the following standards for reduction from the initial luminous efficiency. The results are shown in Table 1 below.
a: Reduction from initial luminous efficiency is less than 5%
b: Reduction from initial luminous efficiency is 5% or more and less than 10%
c: Reduction from initial luminous efficiency is 10% or more and less than 15%
d: Reduction from initial luminous efficiency is 15% or more

TABLE 1

| | | | Ligand | | | | | | | | | | Evaluation | | |
|---|---|---|---|---|---|---|---|---|---|---|---|---|---|---|---|
| | | | | | Structure | | | FT-IR | | | | | | Durability | |
| | | | Structure | Structure | III | | XPS | | | | Peak | Peak | | After | |
| | | | I | II | Hydro- | | Detec- | | | | inten- | inten- | | irradiation | In the |
| | Core | | Mercapto | PEG | carbon | Molec- | tion | Peak | | | sity | sity | | of | case of |
| | compo- | | group | chain (n | group (m | ular | ele- | A | B | C | ratio | ratio | | ultraviolet | being |
| | sition | Type | (numbers) | number) | number) | weight | ments | I_{CH} | I_{PEG} | I_{SH} | B/A | C/A | Initial | rays | diluted |
| Example | In- | A-1 | 3 | 3 | 11 | 831 | C, O, S | Pre- | Pre- | Pre- | 1.0 | 0.06 | A | a | a |
| 1 | based | | | | | | | sent | sent | sent | | | | | |
| Example | In- | A-2 | 3 | 6 | 11 | 950 | C, O, S | Pre- | Pre- | Pre- | 1.5 | 0.06 | B | a | a |
| 2 | based | | | | | | | sent | sent | sent | | | | | |
| Example | In- | A-3 | 2 | 3 | 12 | 813 | C, O, S | Pre- | Pre- | Pre- | 0.8 | 0.04 | A | b | b |
| 3 | based | | | | | | | sent | sent | sent | | | | | |
| Example | In- | A-4 | 2 | 3 | 12 | 813 | C, O, S | Pre- | Pre- | Pre- | 0.8 | 0.04 | A | b | b |
| 4 | based | | | | | | | sent | sent | sent | | | | | |
| Example | In- | A-5 | 3 | 44 | 2 | 7700 | C, O, S | Pre- | Pre- | Pre- | 8.0 | 0.20 | D | a | a |
| 5 | based | | | | | | | sent | sent | sent | | | | | |
| Compar- | Cd- | A-5 | 3 | 44 | 2 | 7700 | C, O, S | Pre- | Pre- | Pre- | 8.0 | 0.20 | A | a | a |
| ative | based | | | | | | | sent | sent | sent | | | | | |
| Example | | | | | | | | | | | | | | | |
| 1 | | | | | | | | | | | | | | | |

| | | | | | | | | | | | |
|---|---|---|---|---|---|---|---|---|---|---|---|
| Compar- | Cd- | JP4181435B | C, O, S | — | — | — | — | — | A | d | d |
| ative | based | (mercapto group: one) | | | | | | | | | |
| Example | | | | | | | | | | | |
| 2 | | | | | | | | | | | |
| Compar- | In- | | C, O, S | — | — | — | — | — | D | d | d |
| ative | based | | | | | | | | | | |
| Example | | | | | | | | | | | |
| 3 | | | | | | | | | | | |
| Compar- | Cd- | JP2002-121549A | C, O, S | — | — | — | — | — | B | d | d |
| ative | based | (mercapto group: one) | | | | | | | | | |
| Example | | | | | | | | | | | |
| 4 | | | | | | | | | | | |
| Compar- | In- | | C, O, S | — | — | — | — | — | C | d | d |
| ative | based | | | | | | | | | | |
| Example | | | | | | | | | | | |
| 5 | | | | | | | | | | | |

From the results shown in Table 1, it was found that, in the case where carbon, oxygen, and sulfur were detected by XPS, peak A, peak B, and peak C were detected by FT-IR, and a ligand containing two or more mercapto groups was present, the semiconductor nanoparticles having an excellent durability comparable to Comparative Example 1 using Cd-based semiconductor nanoparticles were obtained (Examples 1 to 5).

Further, from the comparison between Examples 1 to 4 and Example 5, it was found that the initial luminous efficiency was improved in the case where the peak intensity ratio (I_{PEG}/I_{CH}) between peak A (I_{CH}) and peak B (I_{PEG}) detected by FT-IR was more than 0 and less than 2.5.

Further, from the comparison between Example 1 and Examples 3 and 4, it was found that the durability was further improved in the case where the peak intensity ratio (I_{SH}/I_{CH}) between peak A (I_{CH}) and peak C (I_{SH}) detected by FT-IR was more than 0.05 and less than 0.10.

Further, from the comparison between Example 1 and Example 2, it was found that the initial luminous efficiency was improved in the case where n in Formula (IIa) representing Structure II was an integer of 1 to 5.

On the other hand, it was found that since the ligand prepared by the method described in JP2002-121549A and JP4181435B has only one mercapto group in the ligand, the durability was inferior even in the case of being applied to In-based semiconductor nanoparticles.

What is claimed is:

1. A semiconductor nanoparticle comprising:
a core containing a Group III element and a Group V element,
wherein the nanoparticle contains carbon, oxygen, and sulfur, as detected by X-ray photoelectron spectroscopy, has peak A located at 2800 cm⁻¹ to 3000 cm⁻¹, peak B located at 1000 cm⁻¹ to 1200 cm⁻¹, and peak C located at 2450 cm⁻¹ to 2650 cm⁻¹, as detected by Fourier transform infrared spectroscopy, and contains a ligand having two or more mercapto groups.

2. The semiconductor nanoparticle according to claim 1, wherein a peak intensity ratio between peak A and peak B satisfies Equation (1).
0<peak B/peak A<2.5 (1)

3. The semiconductor nanoparticle according to claim 1, wherein the peak intensity ratio between peak A and peak C satisfies Equation (2).
0<peak C/peak A<0.15 (2)

4. The semiconductor nanoparticle according to claim 1, wherein the ligand has structure I represented by any one of Formulae (Ia), (Ib), and (Ic), structure II represented by Formula (IIa), and structure III represented by a hydrocarbon group other than structure I and structure II: 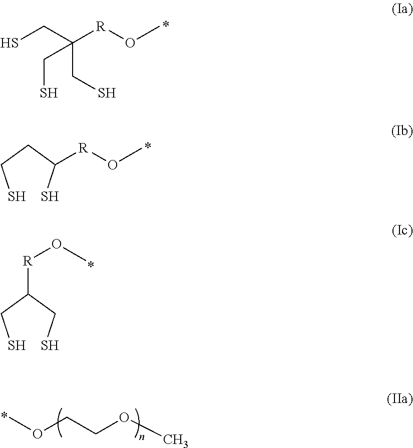
where * in Formulae (Ia) to (Ic), and (IIa) represents a bonding position, R in Formulae (Ia) to (Ic) represents an aliphatic hydrocarbon group having 1 to 8 carbon atoms, and n in Formula (IIa) represents an integer of 1 to 8,

5. The semiconductor nanoparticle according to claim 4, wherein the ligand has structure III between structure I and structure II,
n in Formula (IIa) is an integer of 1 to 5, and
the hydrocarbon group constituting structure III is a linear aliphatic hydrocarbon group having 8 to 25 carbon atoms.

6. The semiconductor nanoparticle according to claim 1, wherein the ligand has an average molecular weight of 300 to 1000.

7. The semiconductor nanoparticle according to claim 1, wherein the ligand has structure IV represented by any one of Formulae (IVa), (IVb), and (IVc): 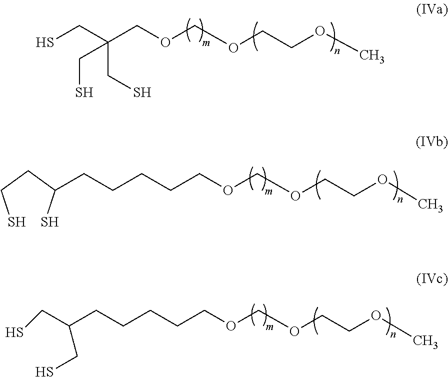
where, in Formulae (IVa) to (IVc), m represents an integer of 8 to 13 and n represents an integer of 2 to 5.

8. The semiconductor nanoparticle according to claim 1, which has a core containing a Group III element and a Group V element and a shell containing a Group II element and a Group VI element and covering at least a part of the surface of the core.

9. The semiconductor nanoparticle according to claim 1, which has a core containing a Group III element and a Group V element, a first shell covering at least a part of the surface of the core, and a second shell covering at least a part of the first shell.

10. The semiconductor nanoparticle according to claim 8, wherein the Group III element contained in the core is In and the Group V element contained in the core is any one of P, N, and As.

11. The semiconductor nanoparticle according to claim 10, wherein the Group III element contained in the core is In and the Group V element contained in the core is P.

12. The semiconductor nanoparticle according to claim 8, wherein the core further contains a Group II element.

13. The semiconductor nanoparticle according to claim 12, wherein the Group II element contained in the core is Zn.

14. The semiconductor nanoparticle according to claim 9, wherein the first shell contains a Group II element or a Group III element, provided that, in the case where the first shell contains a Group III element, the Group III element contained in the first shell is a Group III element different from the Group III element contained in the core.

15. The semiconductor nanoparticle according to claim 9, wherein the first shell is a Group II-VI semiconductor containing a Group II element and a Group VI element, or a Group III-V semiconductor containing a Group III element and a Group V element, provided that, in the case where the first shell is a Group III-V semiconductor, the Group III element contained in the Group III-V semiconductor is a Group III element different from the Group III element contained in the core.

16. The semiconductor nanoparticle according to claim 15, wherein, in the case where the first shell is a Group II-VI semiconductor, the Group II element is Zn and the Group VI element is Se or S, and
in the case where the first shell is a Group III-V semiconductor, the Group III element is Ga and the Group V element is P.

17. The semiconductor nanoparticle according to claim 15, wherein the first shell is a Group III-V semiconductor, the Group III element is Ga, and the Group V element is P.

18. The semiconductor nanoparticle according to claim 9, wherein the second shell is a Group II-VI semiconductor containing a Group II element and a Group VI element, or a Group III-V semiconductor containing a Group III element and a Group V element.

19. The semiconductor nanoparticle according to claim 18, wherein the second shell is a Group II-VI semiconductor, the Group II element is Zn, and the Group VI element is S.

20. The semiconductor nanoparticle according to claim 9, wherein the core, the first shell, and the second shell are all crystal systems having a zinc blende structure.

21. The semiconductor nanoparticle according to claim 9, wherein, among the core, the first shell, and the second shell, the core has the smallest band gap, and the core and the first shell exhibit a type 1 band structure.

22. A dispersion liquid comprising:
the semiconductor nanoparticle according to claim 1.

23. A film comprising:
the semiconductor nanoparticle according to claim 1.
